(19) United States
(12) Patent Application Publication
(10) Pub. No.: US 2020/0024123 A1
(43) Pub. Date: Jan. 23, 2020

(54) LIQUID HANDLING APPARATUS

(71) Applicant: Enplas Corporation, Saitama (JP)

(72) Inventors: Ken KITAMOTO, Saitama (JP); Takumi YAMAUCHI, Saitama (JP)

(21) Appl. No.: 16/499,335

(22) PCT Filed: Mar. 9, 2018
(86) PCT No.: PCT/JP2018/009115

§ 371 Date: Sep. 30, 2019

(30) Foreign Application Priority Data
Mar. 31, 2017 (JP) 2017-071235
Aug. 31, 2017 (JP) 2017-167630

(51) Int. Cl. B81B 1/00; G01N 35/08; B01L 3/00

(52) U.S. Cl. CPC B81B 1/006; B01L 2300/0816; B01L 3/502715; G01N 35/08

(57) ABSTRACT

This liquid handling apparatus has a single introduction part that opens on a first surface side of a substrate and is for introducing a liquid, a plurality of discharge parts that open on the first surface side of the substrate and are for discharging the liquid that has been introduced through the single introduction part, a flow path for connecting the single introduction part and the plurality of discharge parts within the substrate, and a plurality of outflow prevention parts that are disposed so as to surround the openings of the plurality of discharge parts and are for using the surface tension of the liquid to check the progress of the outflow of the liquid from the discharge parts. For each opening part, there are two or more outflow prevention parts disposed so as to surround the opening part.

### TECHNICAL FIELD

The present invention relates to a liquid handling device.

### BACKGROUND ART

In recent years, microchannel chips (flow cells) have been used to accurately and speedily analyze a trace substance such as protein and nucleic acid. Microchannel chips can advantageously handle a small amount of reagents or samples, and are expected to be used for various uses such as laboratory tests, food tests, and environment tests.

The microchannel chip disclosed in PTL 1 includes a supply part for supplying liquid, and a plurality of discharging parts for discharging the provided liquid, and a channel connecting the supply part and the discharging parts. The microchannel chip is composed of an upper substrate and a lower substrate. In the upper substrate, a through hole that serves as the supply part and a plurality of through holes that serve as discharging parts are formed. In the lower substrate, a groove that serves as the channel is formed.

In the microchannel chip disclosed in PTL 1, when liquid is provided to the supply part, the channel is filled with the liquid by capillarity. Next, the liquid filling the channel flows into the discharging part.

### CITATION LIST

### Patent Literature

### PTL 1

### WO2009/145172

### SUMMARY OF INVENTION

### Technical Problem

As described above, in microchannel chips used for various inspections, the capacity of each discharging part may be reduced and the distance between each discharging part may be reduced so as to reduce the size of the microchannel chip in some situation. In such microchannel chips, however, the liquid may flow out of the discharging part after the inspection, and the liquid may be mixed with liquid that flows out from another discharging part.

In view of this, an object of the present invention is to provide a liquid handling device that can prevent liquids retained in discharging parts from making contact with each other between the discharging parts.

### Solution to Problem

A liquid handling device of an embodiment of the present invention includes one introduction part that opens at a first surface of a substrate, the one introduction part being configured to introduce liquid; a plurality of discharging parts that open at the first surface of the substrate, the plurality of discharging parts being configured to discharge the liquid introduced from the one introduction part; a channel configured to connect the one introduction part and the plurality of discharging parts in the substrate; and a plurality of outflow preventing parts disposed to surround respective openings of the plurality of discharging parts, the plurality of outflow preventing parts being configured to prevent advancement of outflow of the liquid from the plurality of discharging parts by using surface tension. Two or more of the plurality of outflow preventing parts are disposed for each opening so as to surround each opening.

### Advantageous Effects of Invention

According to the present invention, it is possible to provide a liquid handling device that can prevent liquids retained in discharging parts from making contact with each other between the discharging parts.

### BRIEF DESCRIPTION OF DRAWINGS

FIGS. 1A to 1C illustrate a configuration of a microchannel chip according to Embodiment 1 of the present invention;

FIG. 2 is a partially enlarged sectional view of the region surrounded by the dotted line in FIG. 1B;

FIGS. 3A to 3D are schematic views for describing an operation of the microchannel chip according to Embodiment 1;

FIGS. 4A to 4C illustrate a configuration of a microchannel chip according to Embodiment 2 of the present invention;

FIG. 5 is a partially enlarged sectional view of the region surrounded by the dotted line in FIG. 4B;

FIGS. 6A to 6E are schematic views for describing an operation of the microchannel chip according to Embodiment 2;

FIGS. 7A to 7C illustrate a configuration of a microchannel chip according to Embodiment 3 of the present invention;

FIG. 8 is a partially enlarged sectional view of the region surrounded by the dotted line in FIG. 7B;

FIGS. 9A to 9C are schematic views for describing an operation of the microchannel chip according to Embodiment 3;

FIGS. 10A to 10C illustrate a configuration of a microchannel chip according to Embodiment 4 of the present invention;

FIG. 11 is a partially enlarged sectional view of the region surrounded by the dotted line in FIG. 10B;

FIGS. 12A to 12D are diagrams for describing an operation of the microchannel chip according to Embodiment 4;

FIG. 13 is a sectional view of a microchannel chip according to Embodiment 5;

FIGS. 14A to 14C are diagrams for describing a method of manufacturing the microchannel chip according to Embodiment 5;

FIG. 15 is a sectional view of a microchannel chip according to Embodiment 6;

FIGS. 16A to 16C are diagrams for describing a method of manufacturing the microchannel chip according to Embodiment 6;

FIG. 17 is a sectional view of a microchannel chip according to Embodiment 7;

FIGS. 18A to 18C are diagrams for describing a method of manufacturing the microchannel chip according to Embodiment 7;

FIG. 19 is a sectional view of a microchannel chip according to Embodiment 8; and

FIGS. 20A to 20C are diagrams for describing a method of manufacturing the microchannel chip according to Embodiment 8.

### DESCRIPTION OF EMBODIMENTS

Embodiments of the present invention are elaborated below with reference to the accompanying drawings. In the following description, a microchannel chip (flow cell) is described as a typical example of the liquid handling device of the present invention.

### Embodiment 1

### Configuration of Microchannel Chip

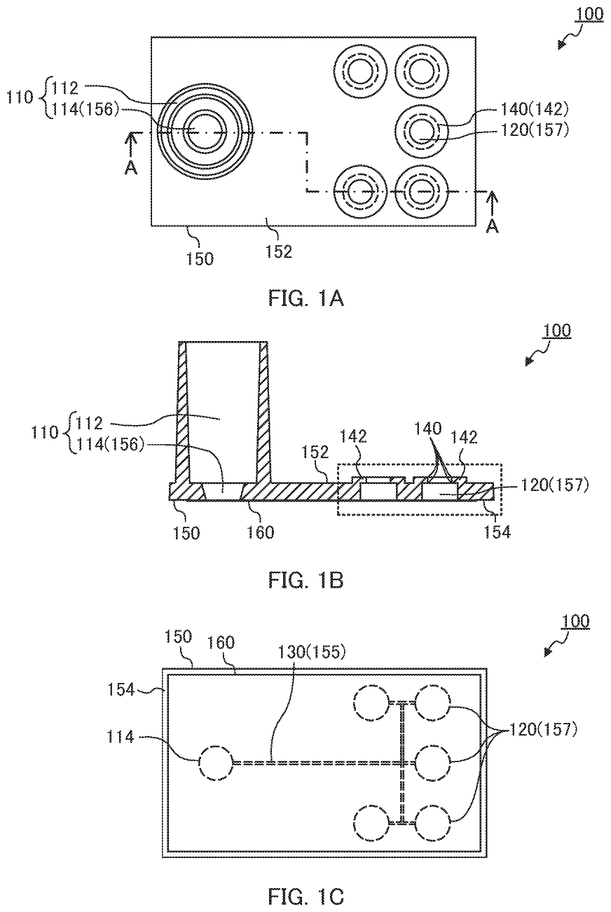

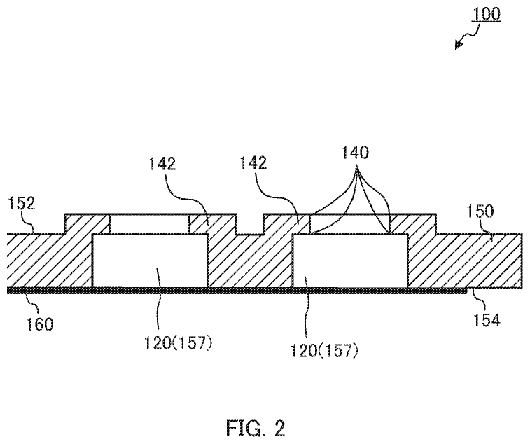

FIGS. 1A to 1C and FIG. 2 illustrate a configuration of microchannel chip 100 according to Embodiment 1 of the present invention. FIG. 1A is a plan view of microchannel chip 100, FIG. 1B is a sectional view taken along line A-A of FIG. 1A, and FIG. 1C is a bottom view of microchannel chip 100. FIG. 2 is a partially enlarged sectional view of the region surrounded by the dotted line in FIG. 1B.

As illustrated in FIGS. 1A to 1C and FIG. 2, microchannel chip 100 includes one introduction part 110, a plurality of discharging parts 120, channel 130, a plurality of outflow preventing parts 140. Microchannel chip 100 is composed of substrate 150 and film 160.

Introduction part 110 is an inlet for introducing liquid to channel 130 and discharging part 120. Introduction part 110 includes retainer 112 and inlet 114.

The type of the liquid to be introduced to channel 130 may be appropriately selected. Examples of the liquid include reagent and liquid sample. In addition, the viscosity of the liquid to be introduced to channel 130 may be appropriately selected. In the present embodiment, the viscosity of the liquid is set to a viscosity at which the liquid can advance in channel 130 by capillarity.

Retainer 112 temporarily retains the liquid to be introduced to channel 130. Retainer 112 is disposed on the side same as top surface 152 of substrate 150 on which the plurality of outflow preventing parts 140 are disposed. The shape of retainer 112 may be appropriately set as long as liquid can be temporarily retained. In the present embodiment, retainer 112 is a substantially cylindrical space disposed above inlet 114. Retainer 112 is surrounded by a side wall. Since the liquid inside retainer 112 is finally housed in the plurality of discharging parts 120, the volume of retainer 112 is normally greater than the volume of each discharging part 120. As such, it is preferable that the distance between the opening of introduction part 110 and the top surface 152 (first surface) of substrate 150 is greater than the distance between the opening of discharging part 120 and the top surface 152.

Inlet 114 guides the liquid retained in retainer 112 to channel 130. The upper opening of inlet 114 is communicated with retainer 112, and the side opening of introduction part 110 is communicated with channel 130. The shape of inlet 114 may be appropriately set as long as the liquid retained in retainer 112 can be guided to channel 130. In the present embodiment, the shape of inlet 114 is a bottomed recess whose diameter gradually decreases from retainer 112 toward channel 130.

Channel 130 is a channel through which liquid can move by capillarity, and channel 130 has a branch. The upstream end of channel 130 is connected with introduction part 110 (inlet 114), and a plurality of downstream ends of channel 130 are connected with respective discharging parts 120.

The plurality of discharging parts 120 are housing parts that retain liquid incoming from channel 130, and cause a desired reaction as necessary. In addition, the liquid in discharging part 120 is discharged to the outside from the opening of discharging part 120. Discharging part 120 functions also as an air hole for introducing liquid to channel 130. The plurality of discharging parts 120 are communicated with the downstream ends of channel 130. The shape of discharging part 120 may be appropriately set as long as the liquid from channel 130 can be retained. The shape of discharging part 120 may be a shape whose diameter gradually increases from the bottom toward the opening, a shape whose diameter gradually decreases from the bottom toward the opening, or a shape whose diameter is identical between the bottom and the opening.

In the present embodiment, discharging part 120 has a shape of a bottomed recess whose diameter is identical between the bottom and the opening.

The plurality of outflow preventing parts 140 are disposed so as to surround the openings of respective discharging parts 120, and prevent advancement of outflow of the liquid from the openings of discharging part 120 by using the surface tension of the liquid.

In microchannel chip 100 according to the present embodiment, two or more outflow preventing parts 140 are disposed for each opening so as to surround the opening. The configuration of outflow preventing part 140 may be appropriately set as long as advancement of the liquid from the opening of discharging part 120 can be prevented by using the surface tension of the liquid. For example, outflow preventing part 140 is (A) an opening edge of discharging part 120, (B) a step that is disposed in the inner surface of discharging part 120 so as to surround the opening and is formed to extend toward the outside from the center side of discharging part 120, (C) an annular groove that is disposed outside the opening so as to surround the opening, or (D) eaves part 142 extending from the inner surface of the discharging part toward the opening. In the present embodiment, outflow preventing part 140 is (D) eaves part 142 extending from the inner surface of discharging part 120 toward the center of the opening, and (A) the opening edge of discharging part 120. More specifically, as illustrated in FIG. 2, the lower opening edge of eaves part 142 is outflow preventing part 140 of (D), and the upper opening edge of eaves part 142 is outflow preventing part 140 of (A).

Eaves part 142 is an annular plate-shaped member disposed at the inner surface of discharging part 120. The internal diameter of eaves part 142 in plan view of eaves part 142 may be appropriately set as long as it is smaller than the diameter of the opening of discharging part 120. In addition, the thickness of eaves part 142 may be appropriately set.

In the above-mentioned manner, microchannel chip 100 is composed of substrate 150 and film 160. Substrate 150 is a substantially rectangular transparent resin substrate. Substrate 150 includes channel groove 155, first through hole 156, and a plurality of second through holes 157.

Of two surfaces of substrate 150, channel groove 155 is formed in bottom surface 154 (second surface) on the side opposite to top surface 152 (first surface) where retainer 112 and outflow preventing part 140 are disposed. One end of channel groove 155 is communicated with first through hole 156. The other end of channel groove 155 has a branch, and is communicated with respective second through holes 157. When the opening of channel groove 155 is covered with film 160, channel groove 155 serves as channel 130.

First through hole 156 is a through hole that opens at the top surface 152 and bottom surface 154 of substrate 150. First through hole 156 is communicated with the upstream end of channel groove 155. The shape of first through hole 156 may be appropriately set. In the present embodiment, first through hole 156 has a shape whose diameter gradually decreases from top surface 152 toward bottom surface 154. When the opening on bottom surface 154 side is covered with film 160, first through hole 156 serves as inlet 114.

In addition, a side wall extending in the thickness direction of substrate 150 is disposed so as to surround the upper opening of first through hole 156. This side wall defines retainer 112.

The plurality of second through holes 157 are through holes that open at the top surface 152 and bottom surface 154 of substrate 150. The plurality of second through holes 157 are communicated with respective downstream ends of channel groove 155. The shape of second through hole 157 may be appropriately set. In the present embodiment, second through hole 157 has a shape whose diameter is identical from the opening of bottom surface 154 side to the opening of top surface 152 side. When the opening on bottom surface 154 side is covered with film 160, each second through hole 157 serves as discharging part 120.

In addition, eaves part 142 is disposed so as to close a part of the opening of second through hole 157 on top surface 152 side. As described above, each of the lower opening edge and the upper opening edge (the opening edge of discharging part 120) of the opening of eaves part 142 functions as the outflow preventing part 140.

The kind of the resin of substrate 150 is not limited and may be appropriately selected from publicly known resins as long as the surface (the surface serving as the internal wall of the channel) that allows liquid to advance channel 130 by capillarity, the adhesion strength to film 160, and the resistance to thermal hysteresis and reagent during various processes can be ensured. The examples of the resin of substrate 150 include polyethylene terephthalate, polycarbonate, polymethylmethacrylate, vinyl chloride, polypropylene, polyether, polyethylene, polystyrene, silicone resin and the like. Substrate 150 has a thickness of 1 to 10 mm for example.

Film 160 is a transparent resin film joined to bottom surface 154 of substrate 150. For example, film 160 and substrate 150 are joined together by thermal compression bonding. Film 160 covers the opening of first through hole 156 on the bottom surface 154 side, the opening of channel groove 155, and the openings of the plurality of second through holes 157 on bottom surface 154 side. The type of the resin of film 160 may be selected from the resin for substrate 150. The resin of film 160 may be identical to that of substrate 150. The thickness of film 160 may be appropriately set in accordance with the resin type (rigidity) as long as the above-described function can be ensured. In the present embodiment, film 160 has a thickness of about 20 μm.

### Operation of Microchannel Chip

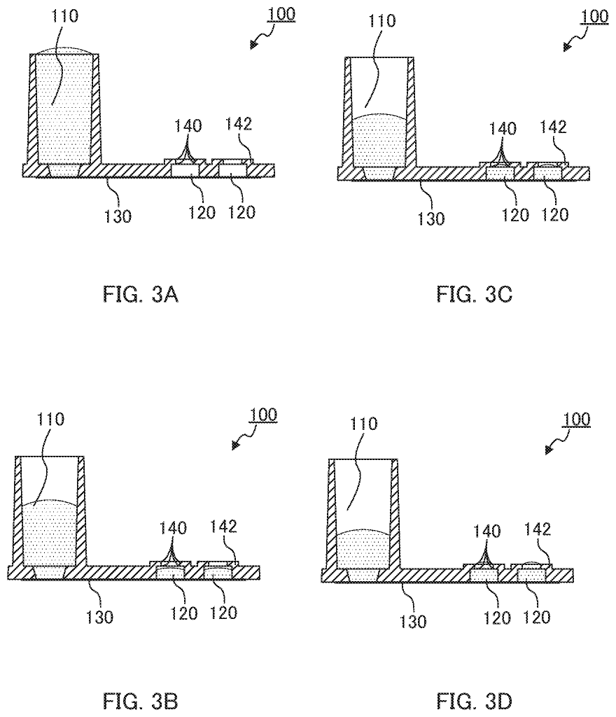

Next, an operation of microchannel chip 100 is described. FIGS. 3A to 3D are schematic views for describing an operation of microchannel chip 100. Note that the following description will be made on the assumption that the liquid having an amount greater than the total volume of the plurality of discharging parts 120 is introduced into introduction part 110 to describe an effect of microchannel chip 100 according to the present embodiment.

As illustrated in FIG. 3, first, introduction part 110 is filled with liquid (see FIG. 3A). By capillarity, the liquid filling introduction part 110 flows through channel 130 and reaches discharging part 120 (see FIG. 3B). The liquid having reached discharging part 120 gradually fills discharging part 120, and reaches the lower opening edge of the opening of eaves part 142 (outflow preventing part 140 of the first stage). Then, the movement of the liquid surface is stopped by the surface tension (see FIG. 3C). In this manner, outflow of the liquid from discharging part 120 can be reduced. Further, when discharging part 120 is filled with the liquid, the liquid surface passes over the lower opening edge of the opening of eaves part 142. Then, the liquid reaches the upper opening edge of the opening of eaves part 142 (outflow preventing part 140 of the second stage). At the upper opening edge of the opening of eaves part 142, the opening diameter abruptly changes, and accordingly the movement of the liquid surface is again stopped by the surface tension (see FIG. 3D). Thus, with outflow preventing part 140 with the two stages, microchannel chip 100 according to the present embodiment can more reliably prevent outflow of the liquid from discharging part 120.

### Effect

With the above-mentioned configuration, with the lower opening edge (outflow preventing part 140 of the first stage) of the opening of eaves part 142 and the upper opening edge (outflow preventing part 140 of the second stage) of the opening of eaves part 142, microchannel chip 100 according to the present embodiment can reduce outflow of the liquid from discharging part 120. Thus, even if an excessive amount of liquid is introduced into introduction part 110, the possibility of a situation where the liquids retained in discharging parts 120 make contact with each other between discharging parts 120 can be further reduced.

### Embodiment 2

### Configuration of Microchannel Chip

Microchannel chip 200 according to Embodiment 2 differs from microchannel chip 100 according to Embodiment 1 only in the structure of outflow preventing part 240. In view of this, in the present embodiment, outflow preventing part 240 is mainly described. Note that the components similar to those of microchannel chip 100 according to Embodiment 1 are denoted with the same reference numerals, and the description thereof will be omitted.

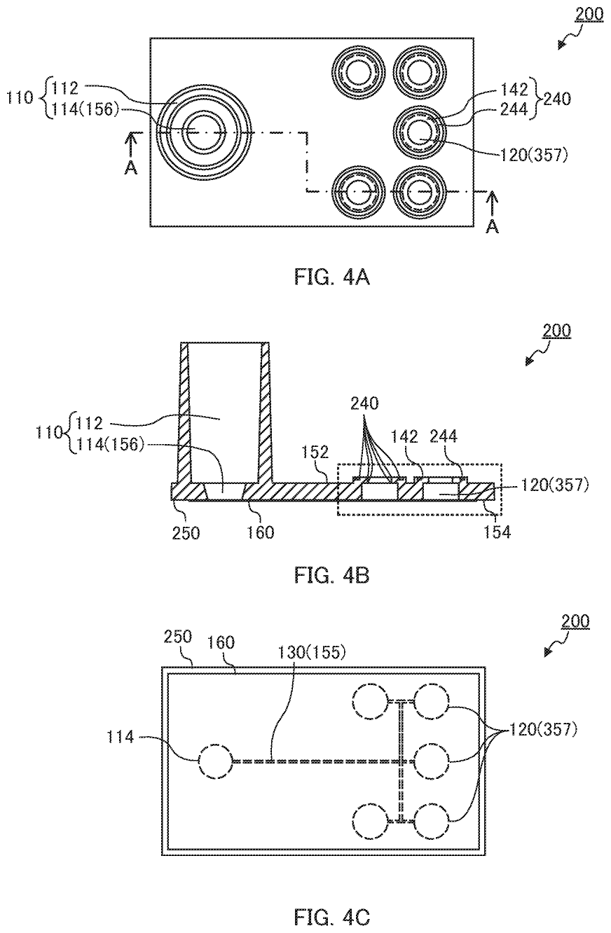

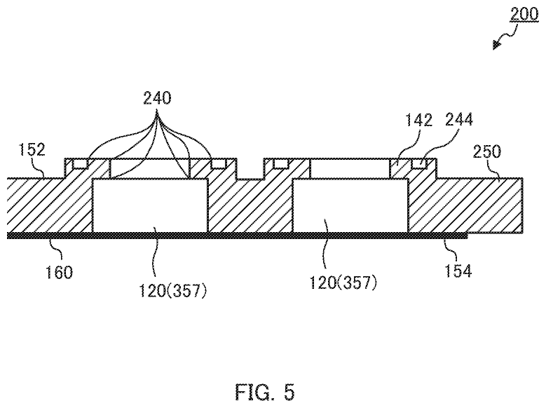

FIGS. 4A to 4C and FIG. 5 illustrate a configuration of microchannel chip 200 according to Embodiment 2. FIG. 4A is a plan view of microchannel chip 200, FIG. 4B is a sectional view taken along line A-A of FIG. 4A, and FIG. 4C is a bottom view of microchannel chip 200. FIG. 5 is a partially enlarged sectional view of the region surrounded by the dotted line in FIG. 4B.

As illustrated in FIGS. 4A to 4C and FIG. 5, microchannel chip 200 includes introduction part 110, channel 130, discharging parts 120, and a plurality of outflow preventing parts 240. Microchannel chip 200 is composed of substrate 250 and film 160.

Substrate 250 includes channel groove 155, first through hole 156, and second through hole 357. In addition, eaves part 142 is disposed at top surface 152 of substrate 250, and annular groove 244 opens at top surface 152 of substrate 250.

In the present embodiment, as outflow preventing part 240, (C) annular groove 244 that is disposed outside the opening so as to surround the opening also functions in addition to (D) eaves part 142 extending from the inner surface of discharging part 120 toward the center of the opening and (A) the opening edge of discharging part 120.

Annular groove 244 is an annular groove that is disposed outside the opening of discharging part 120 so as to surround the opening of discharging part 120. In the present embodiment, annular groove 244 is disposed in the top surface of eaves part 142. The width and depth of annular groove 244 are not limited as long as movement of liquid passing over annular groove 244 can be reduced, and may be appropriately set in accordance with the location where annular groove 244 is disposed. While one annular groove 244 is provided for each discharging part 120 in microchannel chip 200 in the present embodiment, a plurality of annular grooves 244 may be provided for each discharging part 120. In this case, annular grooves 244 are concentrically disposed about the center of the opening of discharging part 120.

### Operation of Microchannel Chip

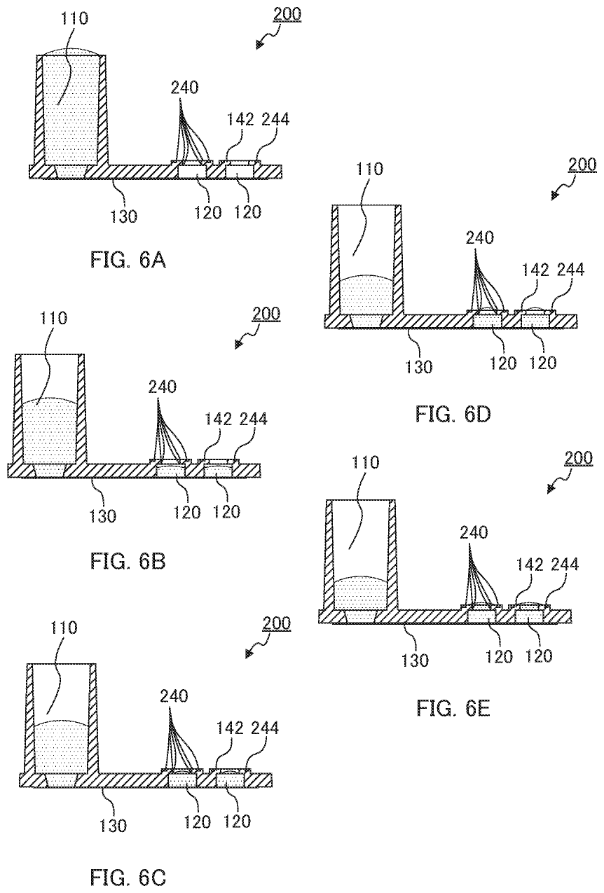

Next, an operation of microchannel chip 200 is described. FIGS. 6A to 6E are schematic views for describing an operation of microchannel chip 200. The following description will be made on the assumption that liquid having an amount greater than the total volume of the plurality of discharging parts 120 is introduced into introduction part 110 to describe an effect of microchannel chip 200 according to the present embodiment.

As illustrated in FIG. 6, first, introduction part 110 is filled with liquid (see FIG. 6A). By capillarity, the liquid filling introduction part 110 flows through channel 130 and reaches discharging part 120 (see FIG. 6B). The liquid having reached discharging part 120 gradually fills discharging part 120, and reaches the lower opening edge of the opening of eaves part 142 (outflow preventing part 240 of the first stage). Then, the movement of the liquid surface is stopped by the surface tension (see FIG. 6C). In this manner, outflow of the liquid from discharging part 120 can be reduced. Further, when discharging part 120 is filled with the liquid, the liquid passes over the lower opening edge of the opening of eaves part 142. Then, the liquid reaches the upper opening edge of the opening of eaves part 142 (outflow preventing part 240 of the second stage). At the upper opening edge of the opening of eaves part 142 (the opening edge of discharging part 120), the opening diameter abruptly changes, and accordingly the movement of the liquid surface is again stopped by the surface tension (see FIG. 6D). In this manner, outflow of liquid from discharging part 120 can be prevented. Further, when discharging part 120 is filled with the liquid, the liquid passes over the upper opening edge of the opening. Then, the liquid reaches the inner end portion of annular groove 244 (outflow preventing part 240 of the third stage). Again, the movement of the liquid surface is stopped by the surface tension (see FIG. 6E). Thus, with outflow preventing part 240 with the three stages, microchannel chip 200 according to the present embodiment can more reliably prevent outflow of the liquid from discharging part 120.

### Effect

In the above-mentioned manner, with eaves part 142 extending from the inner surface of discharging part 120 toward the center of the opening (outflow preventing part 240 of the first stage), the opening edge of discharging part 120 (outflow preventing part 240 of the second stage), and annular groove 244 that is disposed outside the opening so as to surround the opening (outflow preventing part 240 of the third stage), microchannel chip 200 according to the present embodiment can reduce outflow of the liquid from discharging part 120, and can limit expansion of the liquid that has flown out from liquid discharging part 120. Thus, the possibility of a situation where the liquids retained in discharging parts 120 make contact with each other between discharging parts 120 can be further reduced.

### Embodiment 3

### Configuration of Microchannel Chip

Microchannel chip 300 according to Embodiment 3 differs from microchannel chip 100 according to Embodiment 1 only in the structure of outflow preventing part 340. In view of this, in the present embodiment, outflow preventing part 340 is mainly described.

Note that the components similar to those of microchannel chip 100 according to Embodiment 1 are denoted with the same reference numerals, and the description thereof will be omitted.

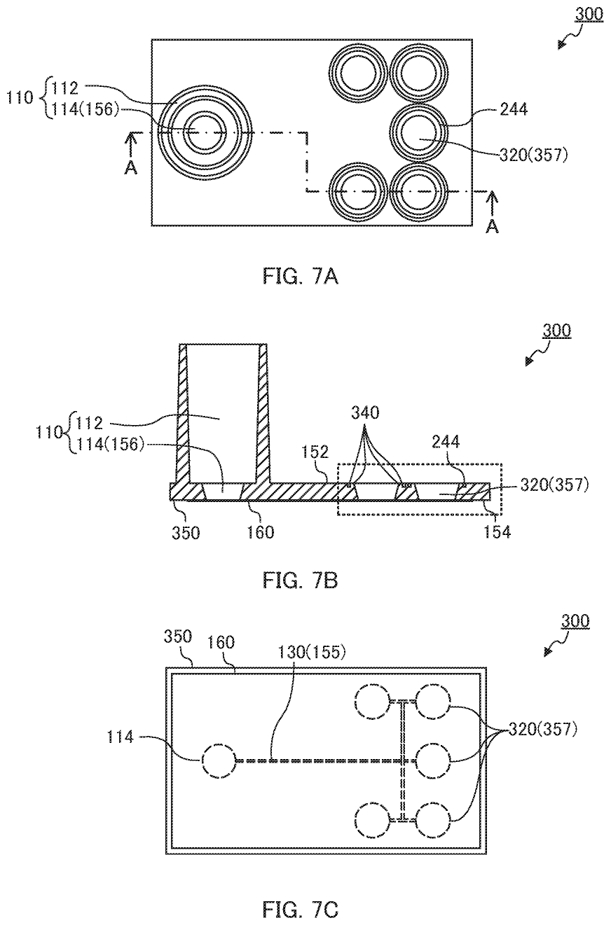

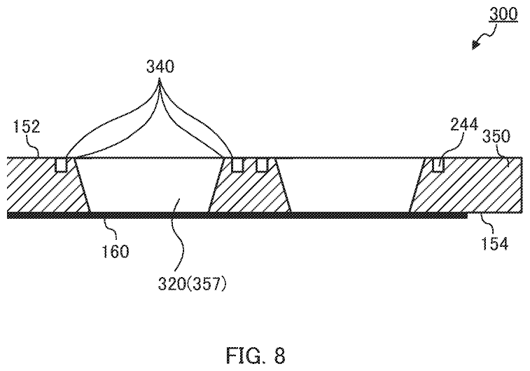

FIGS. 7A to 7C and FIG. 8 illustrate a configuration of microchannel chip 300 according to Embodiment 3. FIG. 7A is a plan view of microchannel chip 300, FIG. 7B is a sectional view taken along line A-A of FIG. 7A, and FIG. 7C is a bottom view of microchannel chip 300. FIG. 8 is a partially enlarged sectional view of the region surrounded by the dotted line in FIG. 7B.

As illustrated in FIGS. 7A to 7C and FIG. 8, microchannel chip 300 includes introduction part 110, channel 130, a plurality of discharging parts 320, and a plurality of outflow preventing parts 340. Microchannel chip 300 is composed of substrate 350 and film 160.

The plurality of discharging parts 320 are housing parts that retain liquid coming from channel 130, and cause a desired reaction as necessary. The liquid in discharging part 320 is discharged to the outside from the opening of discharging part 320. Discharging part 320 functions also as an air hole for introducing liquid to channel 130.

The plurality of discharging parts 320 are communicated with the downstream end of channel 130. In the present embodiment, discharging part 320 is a bottomed recess whose diameter gradually increases from the bottom toward the opening.

In the present embodiment, (A) the opening edge of discharging part 320, and (C) annular groove 244 that is disposed outside the opening so as to surround the opening function as outflow preventing part 340. Annular groove 244 is disposed outside the opening of discharging part 320 so as to surround the opening in top surface 152.

Substrate 350 includes channel groove 155, first through hole 156 and second through hole 357. In addition, annular groove 244 is open at top surface 152 of substrate 350. Second through hole 357 is a through hole that opens at top surface 152 and bottom surface 154, and is a bottomed recess whose diameter gradually increases from bottom surface 154 toward top surface 152. When the openings of the plurality of second through holes 357 on bottom surface 154 side is covered with film 160, each through holes 357 serves as discharging part 320.

### Operation of Microchannel Chip

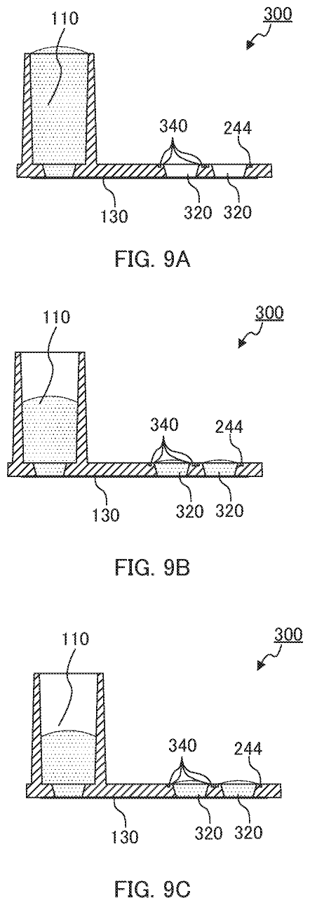

Next, an operation of microchannel chip 300 is described. FIGS. 9A to 9C are schematic views for describing an operation of microchannel chip 300. The following description will be made on the assumption that liquid having an amount greater than the total volume of the plurality of discharging parts 120 is introduced into introduction part 110 to describe an effect of microchannel chip 300 according to the present embodiment.

As illustrated in FIG. 9, first, introduction part 110 is filled with liquid (see FIG. 9A). By capillarity, the liquid filling introduction part 110 flows through channel 130 and reaches discharging part 320. The liquid having reached discharging part 320 gradually fills discharging part 320, and reaches the opening edge of discharging part 320 (outflow preventing part 340 of the first stage). At the opening edge of discharging part 320, the opening diameter abruptly changes, and accordingly the movement of the liquid surface is stopped by the surface tension (see FIG. 9B). In this manner, outflow of the liquid from discharging part 320 can be prevented. Further, when discharging part 120 is filled with the liquid, the liquid passes over the opening edge of discharging part 320. Then, the liquid reaches the inner end portion of annular groove 244 (outflow preventing part 240 of the second stage). Again, the movement of the liquid surface is stopped by the surface tension (see FIG. 9C). Thus, with outflow preventing part 340 with the two stages, microchannel chip 300 according to the present embodiment can more reliably prevent outflow of the liquid from discharging part 320.

Effect

In the above-mentioned manner, with the opening edge of discharging part 320 (outflow preventing part 340 of the first stage), and annular groove 244 that is disposed outside the opening so as to surround the opening (outflow preventing part 240 of the second stage), microchannel chip 300 according to the present embodiment can reduce outflow of the liquid from discharging part 320, and can limit expansion of the liquid that has flown out from liquid discharging part 320. Thus, even if an excessive amount of liquid is introduced into introduction part 110, the possibility of a situation where the liquids retained in discharging parts 320 make contact with each other between discharging parts 320 can be further reduced.

### Embodiment 4

### Configuration of Microchannel Chip

Microchannel chip 400 according to Embodiment 4 differs from microchannel chip 100 according to Embodiment 1 only in the structure of outflow preventing part 440. In view of this, in the present embodiment, outflow preventing part 440 is mainly described.

Note that the components similar to those of microchannel chip 100 according to Embodiment 1 are denoted with the same reference numerals, and the description thereof will be omitted.

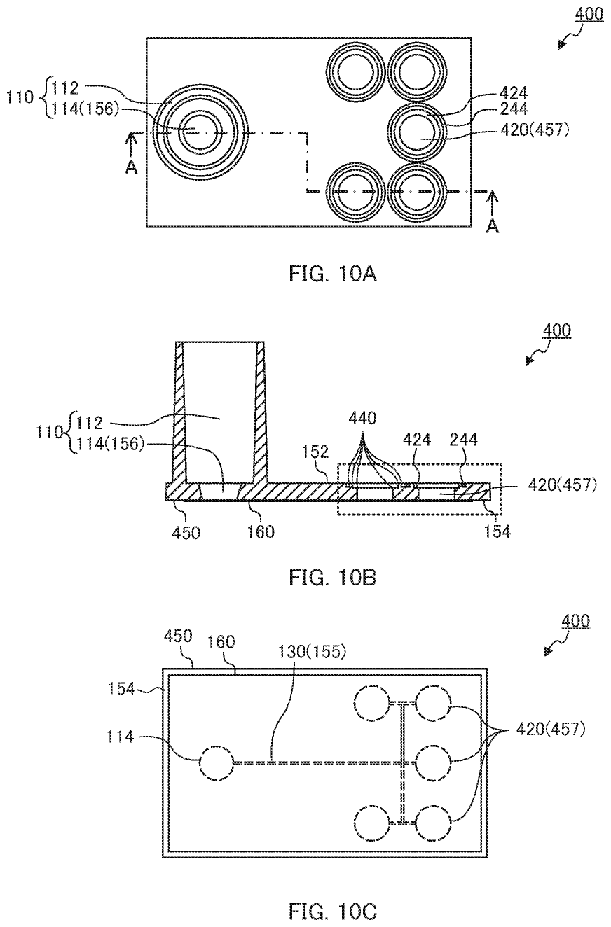

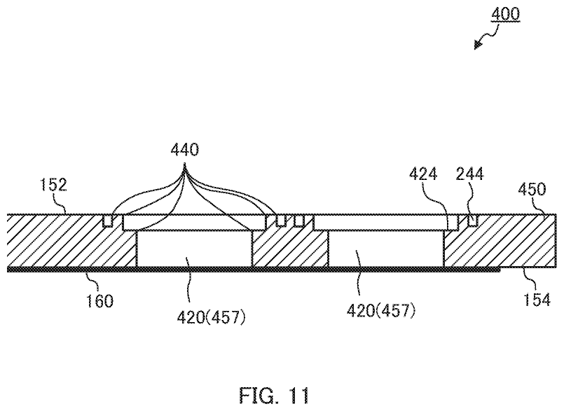

FIGS. 10A to 10C and FIG. 11 illustrate a configuration of microchannel chip 400 according to Embodiment 4. FIG. 10A is a plan view of microchannel chip 400, FIG. 10B is a sectional view taken along line A-A of FIG. 10A, and FIG. 10C is a bottom view of microchannel chip 400. FIG. 11 is a partially enlarged sectional view of the region surrounded by the dotted line in FIG. 10B.

As illustrated in FIGS. 10A to 10C and FIG. 11, microchannel chip 400 includes introduction part 110, channel 130, a plurality of discharging parts 420, and a plurality of outflow preventing parts 440. Microchannel chip 400 is composed of substrate 450 and film 160.

In the present embodiment, (B) step 442 that is formed so as to extend toward the outside from the center side of discharging part 120, (A) the opening edge of discharging part 420, and (C) annular groove 244 that is disposed outside the opening so as to surround the opening function as outflow preventing part 440.

Step 424 is disposed in the inner surface of discharging part 420 so as to extend away from the center side of the opening toward the outside. In the present embodiment, step 424 is a step portion formed between a cylindrical part whose opening area is greater than that of discharging part 420 and the inner surface of discharging part 120.

Substrate 450 includes channel groove 155, first through hole 156, and second through hole 457. In addition, step 424 is formed in top surface 152 of substrate 450 and annular groove 244 is open at top surface 152 of substrate 450.

### Operation of Microchannel Chip 400

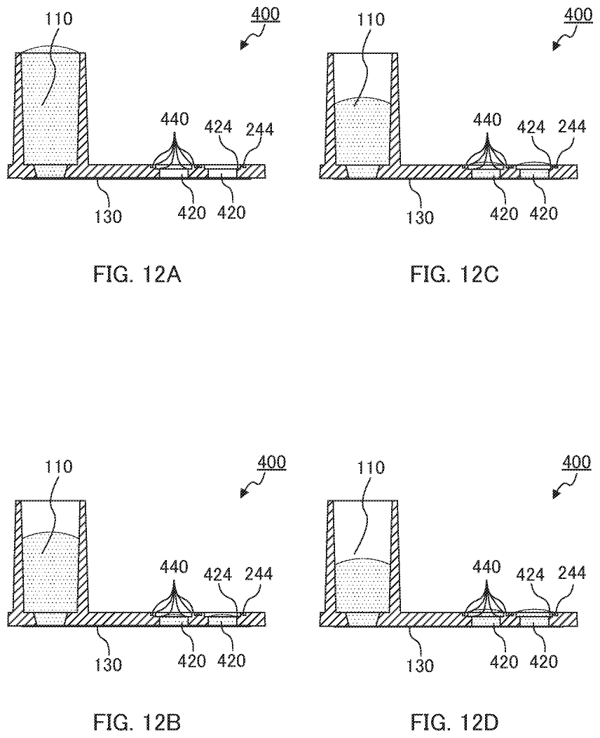

Next, an operation of microchannel chip 400 is described. FIGS. 12A to 12D are schematic views for describing an operation of microchannel chip 400. The following description will be made on the assumption that liquid having an amount greater than the total volume of the plurality of discharging parts 120 is introduced into introduction part 110 to describe an effect of microchannel chip 400 according to the present embodiment.

As illustrated in FIG. 12, first, introduction part 110 is filled with liquid (see FIG. 12A). By capillarity, the liquid filling introduction part 110 flows through channel 130 and reaches discharging part 420. The liquid having reached discharging part 420 gradually fills discharging part 420, and reaches step 424 (outflow preventing part 440 of the first stage). At step 424, the opening diameter abruptly changes, and accordingly the movement of the liquid surface is stopped by the surface tension (see FIG. 12B). In this manner, outflow of the liquid from discharging part 420 is reduced. Further, when discharging part 420 is filled with the liquid, the liquid passes over surface step 424. Then, the liquid reaches the opening edge of discharging part 420 (outflow preventing part 440 of the second stage). At the opening edge of discharging part 420, the opening diameter abruptly changes, and accordingly the movement of the liquid surface is stopped by the surface tension (see FIG. 12C). In this manner, outflow of the liquid from discharging part 420 can be reduced. Further, when discharging part 420 is filled with the liquid, the liquid passes over the opening edge of discharging part 420. Then, the liquid reaches the inner end portion of annular groove 244 (outflow preventing part 240 of the third stage). Again, the movement of the liquid surface is stopped by the surface tension (FIG. 12D). Thus, with outflow preventing part 440 with the three stages, microchannel chip 400 according to the present embodiment can more reliably prevent outflow of the liquid from discharging part 420.

### Effect

In the above-mentioned manner, with step 424 that is formed in the inner surface of discharging part 420 so as to surround the opening and to extend toward the outside from the center side of discharging part 420 (outflow preventing part 440 of the first stage), the opening edge of discharging part 420 (outflow preventing part 440 of the second stage), and annular groove 244 that is disposed outside the opening so as to surround the opening, microchannel chip 400 according to the present embodiment can reduce outflow of the liquid from discharging part 420, and can limit the expansion of the liquid that has flown out from liquid discharging part 420. Thus, even if an excessive amount of liquid is introduced into introduction part 110, the possibility of a situation where the liquids retained in discharging parts 420 make contact with each other between discharging parts 420 can be further reduced.

Note that the combinations and number of outflow preventing parts (A), (B), (C) and (D) may not be those described in Embodiment 1 to 4.

### Embodiment 5

Microchannel chip 500 according to Embodiment 5 is different from microchannel chip 100 according to Embodiment 1 only in that hydrophilic treatment is provided in at least a part of a region. Note that the components similar to those of microchannel chip 100 according to Embodiment 1 are denoted with the same reference numerals, and the description thereof will be omitted.

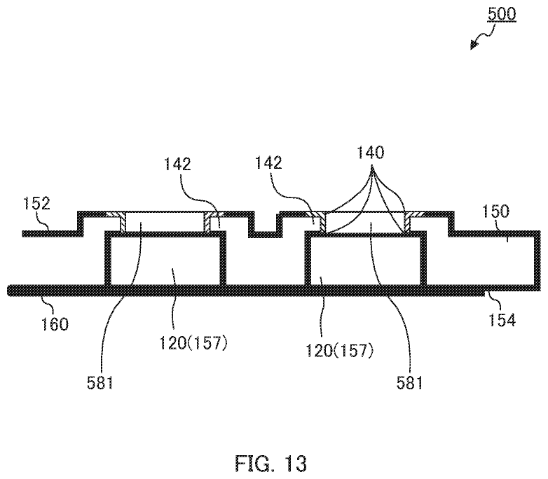

FIG. 13 is a sectional view of microchannel chip 500 according to Embodiment 5. Note that, in FIG. 13, hatching of substrate 150 is omitted for illustration of the hydrophilic region and the hydrophobic region. In FIG. 13, the region illustrated with the thick black lines represents the hydrophilic region, and the hatched region and the reference numeral 581 represent the hydrophobic region.

Microchannel chip 500 includes one introduction part 110, a plurality of discharging parts 120, channel 130, and a plurality of outflow preventing parts 140.

Microchannel chip 500 is composed of substrate 150 and film 160. As illustrated in FIG. 13, in the surface of microchannel chip 500 in the present embodiment, when liquid is continuously introduced from channel 130 into discharging part 120, outflow preventing part 140 where the liquid first reaches is the lower opening edge of eaves part 142. In addition, outflow preventing part 140 where the liquid reaches last is the upper opening edge of eaves part 142. Then, the hydrophilic treatment is provided in at least a part of the region other than the region between the lower opening edge of eaves part 142 and the upper opening edge of eaves part 142. In the present embodiment, the hydrophilic treatment is provided in all regions except for the region between the lower opening edge of eaves part 142 and the upper opening edge of eaves part 142, and for the peripheral region of the opening edge on the top surface of eaves part 142.

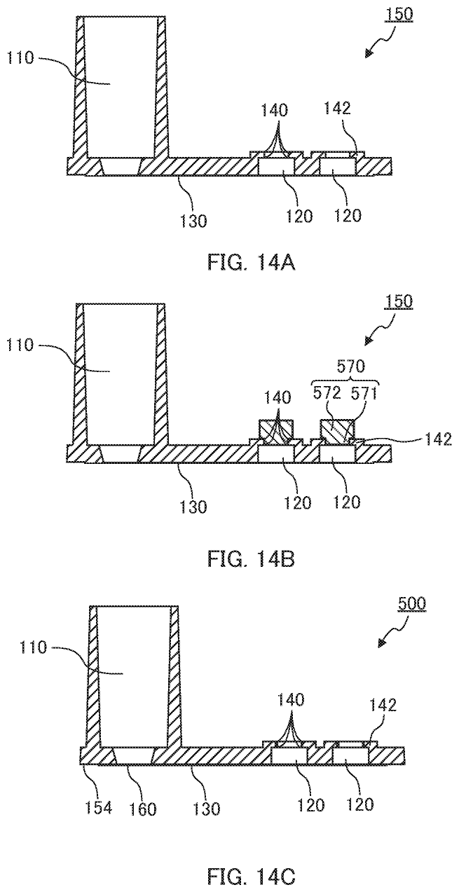

Microchannel chip 500 may be manufactured by the following method, for example. FIGS. 14A to 14C are diagrams for describing a method of manufacturing microchannel chip 500. As illustrated in FIG. 14A, for example, substrate 150 similar to that of Embodiment 1 is manufactured by injection molding or the like.

Next, as illustrated in FIG. 14B, mask member 570 is brought into intimate contact with substrate 150 in the region other than the region where the hydrophilic treatment is provided. The material of mask member 570 may be appropriately selected as long as it can make intimate contact with the region other than the region where the hydrophilic treatment is provided. Examples of the material of mask member 570 include elastic materials such as silicone and rubber. Mask member 570 includes first mask part 571 that makes intimate contact with the inner surface of eaves part 142, and base seat part 572 that makes intimate contact with the periphery of the upper opening edge of eaves part 142.

The method of providing the hydrophilic treatment may be appropriately selected. Examples of the method of providing the hydrophilic treatment include a plasma treatment and an atomic layer deposition (ALD) method. Examples of the thin film formed by the atomic layer deposition (ALD) method include a layer including silicon oxide, a layer including aluminum oxide, and a layer including titanium oxide. With this configuration, hydrophilicity is provided to the regions other than the region masked with mask member 570. In addition, the regions other than the region masked with mask member 570 become hydrophobic in comparison with the region masked with mask member 570. Note that, normally, the surface of an injection-molded article using a commonly used resin has hydrophobicity.

Next, film 160 is joined to bottom surface 154 of substrate 150 after mask member 570 is removed, and thus microchannel chip 500 illustrated in FIG. 14C may be manufactured.

### Effect

With the above-mentioned configuration, microchannel chip 500 according to the present embodiment can easily carry the liquid since the hydrophilicity is provided at the interior of channel 130 and discharging part 120 with the hydrophilic region and the hydrophobic region while achieving the effect of Embodiment 1.

### Embodiment 6

Microchannel chip 600 according to Embodiment 6 is different from microchannel chip 200 according to Embodiment 2 only in that hydrophilic treatment is provided in at least a part of a region. Note that the components similar to those of microchannel chip 200 according to Embodiment 2 are denoted with the same reference numerals, and the description thereof will be omitted.

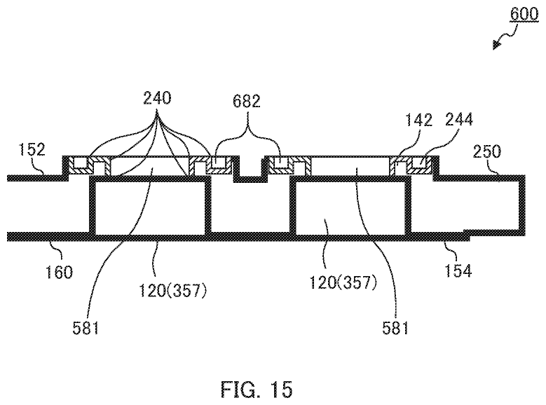

FIG. 15 is a sectional view of microchannel chip 600 according to Embodiment 6. Note that, in FIG. 15, the hatching of substrate 250 is omitted for illustration of the hydrophilic region and the hydrophobic region. In FIG. 15, the thick black line represents the hydrophilic region, and the hatching region and the regions of reference numerals 581 and 682 represent the hydrophobic region.

Microchannel chip 600 includes introduction part 110, channel 130, a plurality of discharging parts 120, and a plurality of outflow preventing parts 240. Microchannel chip 600 is composed of substrate 250 and film 160. As illustrated in FIG. 15, outflow preventing part 240 where the liquid first reaches when liquid is continuously introduced from channel 130 into discharging part 120 at the surface of microchannel chip 600 in the present embodiment is the lower opening edge of eaves part 142. In addition, outflow preventing part 240 where the liquid reaches last is annular groove 244. Further, the hydrophilic treatment is provided in at least a part of the region other than the region between the lower opening edge of eaves part 142 and annular groove 244. In the present embodiment, the hydrophilic treatment is provided in all regions except for the region between the lower opening edge of eaves part 142 and annular groove 244.

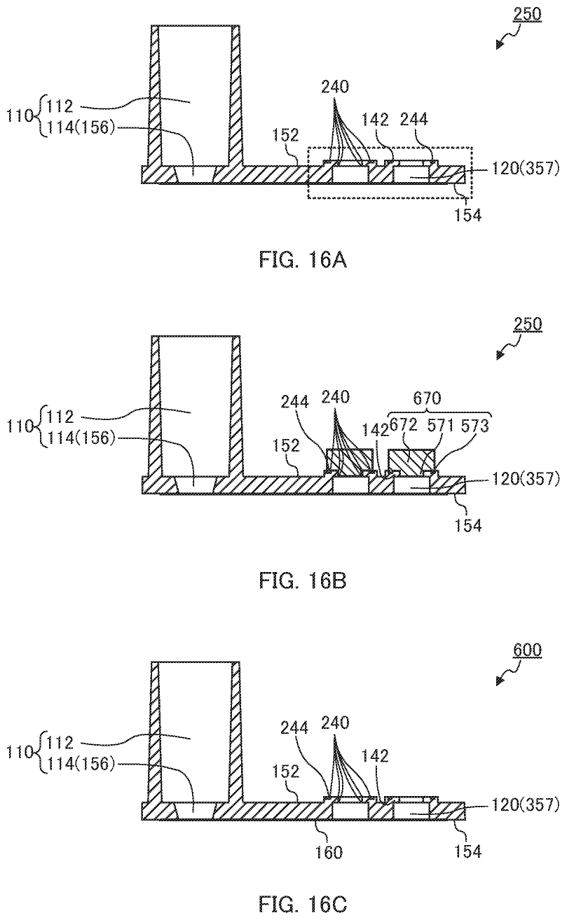

Microchannel chip 600 may be manufactured by the following method, for example. As illustrated in FIGS. 16A to 16C, microchannel chip 600 may be manufactured using mask member 670 as in Embodiment 5. As the material of mask member 670, materials similar to the materials described in Embodiment 5 may be used. In the present embodiment, mask member 670 includes first mask part 571 that makes intimate contact with the inner surface of eaves part 142, second mask part 573 that makes intimate contact with annular groove 244, and base seat part 672 that connects between first mask part 571 and second mask part 573 and makes intimate contact with the region between the upper opening edge of eaves part 142 and annular groove 244.

Effect With the above-mentioned configuration, microchannel chip 600 according to the present embodiment can easily carry the liquid since the hydrophilicity is provided at the interior of channel 130 and discharging part 120 with the hydrophilic region and the hydrophobic region while achieving the effect of Embodiment 2.

### Embodiment 7

Microchannel chip 700 according to Embodiment 7 is different from microchannel chip 300 according to Embodiment 3 only in that hydrophilic treatment is provided in at least a part of a region. Note that the components similar to those of microchannel chip 300 according to Embodiment 3 are denoted with the same reference numerals, and the description thereof will be omitted.

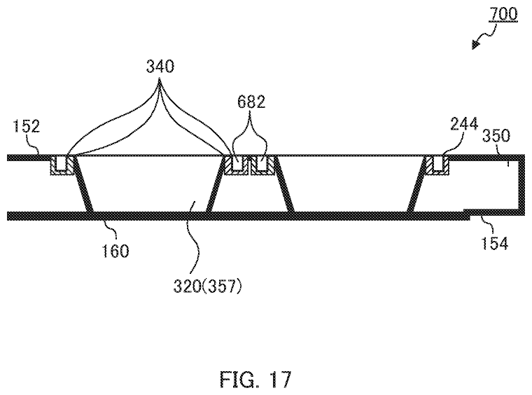

FIG. 17 is a sectional view of microchannel chip 700 according to Embodiment 7.

Note that, in FIG. 17, the hatching of substrate 350 is omitted for illustration of the hydrophilic region and the hydrophobic region. In FIG. 17, the thick black line represents the hydrophilic region, and the hatching region and the reference numeral 682 represent the hydrophobic region.

Microchannel chip 700 includes one introduction part 110, a plurality of discharging parts 320, channel 130 and a plurality of outflow preventing parts 340. In the present embodiment, at the surface of microchannel chip 700, outflow preventing part 340 where the liquid first reaches when the liquid is continuously introduced into discharging part 320 from channel 130 is the opening edge of discharging part 320. In addition, outflow preventing part 340 where the liquid reaches last is annular groove 244. The hydrophilic treatment is provided in at least a part of the region other than the region between the opening edge of discharging part 320 and annular groove 244. In the present embodiment, the hydrophilic treatment is provided in all regions except for the region between the opening edge of discharging part 320 and annular groove 244. The region between the opening edge of discharging part 320 and annular groove 244 is the hydrophobic region.

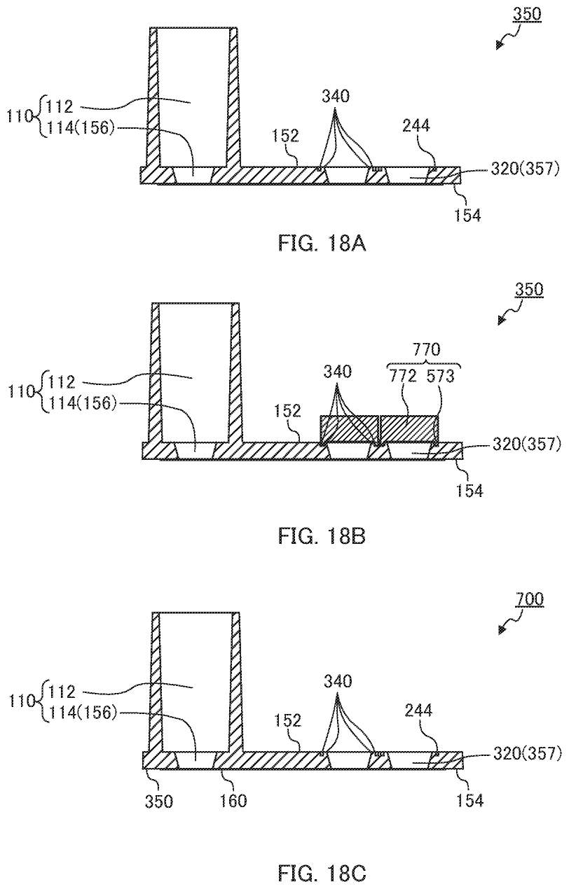

Microchannel chip 700 may be manufactured by the following method, for example. FIGS. 18A to 18C are diagrams for describing a method of manufacturing microchannel chip 700. As illustrated in FIGS. 18A to 18C, the chip may be manufactured using mask member 770 as in Embodiment 6. Mask member 770 according to the present embodiment includes second mask part 573 that makes intimate contact with annular groove 244, and base seat part 772 that makes intimate contact with the region between the upper opening edge of eaves part 142 and annular groove 244. As the material of mask member 770, a member similar to that of Embodiment 5 may be used.

### Effect

With the above-mentioned configuration, microchannel chip 700 according to the present embodiment can easily carry the liquid since the hydrophilicity is provided at the interior of channel 130 and discharging part 320 with the hydrophilic region and the hydrophobic region while achieving the effect of Embodiment 3.

### Embodiment 8

Microchannel chip 800 according to Embodiment 8 is different from microchannel chip 400 according to Embodiment 4 only in that hydrophilic treatment is provided in at least a part of a region. Note that the components similar to those of microchannel chip 400 according to Embodiment 4 are denoted with the same reference numerals, and the description thereof will be omitted.

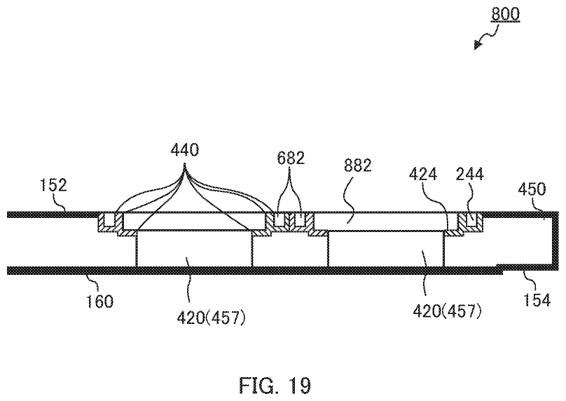

FIG. 19 is a sectional view of microchannel chip 800 according to Embodiment 8. Note that, in FIG. 19, the hatching of substrate 450 is omitted for illustration of the hydrophilic region and the hydrophobic region. In FIG. 19, the thick black line represents the hydrophilic region, and the hatching region and the reference numerals 882 and 682 represent the hydrophobic region.

Microchannel chip 800 includes one introduction part 110, a plurality of discharging parts 420, channel 130 and a plurality of outflow preventing parts 440. Microchannel chip 800 is composed of substrate 450 and film 160. In the present embodiment, at the surface of microchannel chip 800, outflow preventing part 440 where the liquid first reaches when the liquid is continuously introduced into discharging part 420 from channel 130 is the opening edge of discharging part 420. In addition, outflow preventing part 440 where the liquid reaches last is annular groove 244. The hydrophilic treatment is provided in at least a part of the region other than the region between the opening edge of discharging part 420 and annular groove 244. In the present embodiment, the hydrophilic treatment is provided in all regions other than the region between the opening edge of discharging part 420 and annular groove 244.

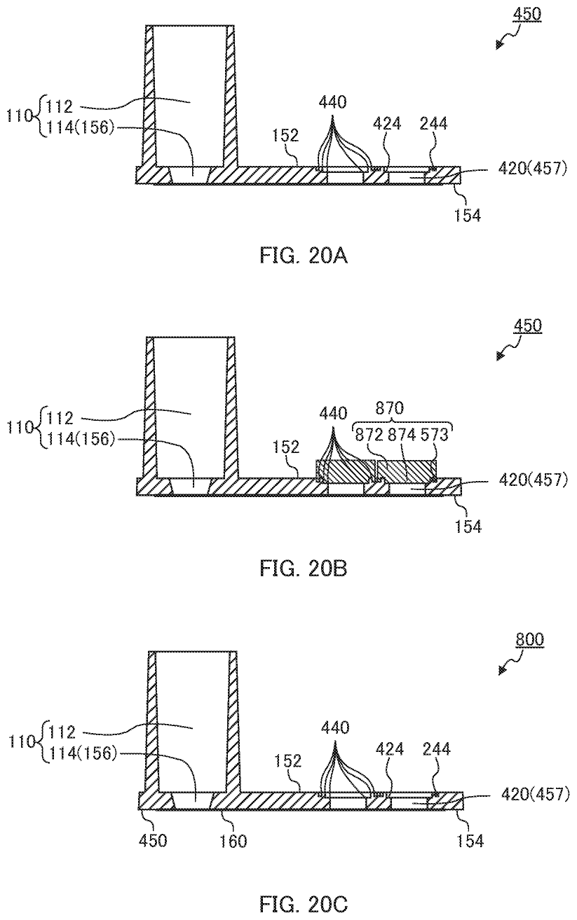

Microchannel chip 800 may be manufactured by the following method, for example. FIGS. 20A to 20C are diagrams for describing a method of manufacturing microchannel chip 800. As illustrated in FIGS. 20A to 20C, microchannel chip 800 may be manufactured using mask member 870 as in Embodiment 6. Mask member 870 according to the present embodiment includes second mask part 573 that makes intimate contact with the annular groove, third mask part 874 that makes intimate contact with step 424, and base seat part 872 that makes intimate contact with the region between second mask part 573 and third mask part 874. As the material of mask member 870, a member similar to that of Embodiment 5 may be used.

### Effect

With the above-mentioned configuration, microchannel chip 800 according to the present embodiment can easily carry the liquid since the hydrophilicity is provided at the interior of channel 130 and discharging part 420 with the hydrophilic region and the hydrophobic region while achieving the effect of Embodiment 4.

This application is entitled to and claims the benefit of Japanese Patent Application No. 2017-071235 filed on Mar. 31, 2017, and Japanese Patent Application No. 2017-167630 filed on Aug. 31, 2017, the disclosure each of which including the specification, drawings and abstract is incorporated herein by reference in its entirety.

### INDUSTRIAL APPLICABILITY

The microchannel chip of embodiments of the present invention is useful as a microchannel chip used in the scientific fields, the medical fields and the like, for example.

### REFERENCE SIGNS LIST

100, 200, 300, 400, 500, 600, 700, 800 Microchannel chip
110 Introduction part
112 Retainer
114 Inlet
120, 320, 420 Discharging part
130 Channel
140, 240, 340, 440 Outflow preventing part
142 Eaves part
150, 250, 350, 450 Substrate
152 Top surface (First surface)
154 Bottom surface (Second surface)
155 Channel groove
156 First through hole
157, 357, 457 Second through hole
160 Film
244 Annular groove
424 Step
570, 670, 770, 870 Mask member
571 First mask part
572, 672, 772, 872 Base seat part
573 Second mask member
581, 682, 882 Hydrophobic region
874 Third mask part

1. A liquid handling device, comprising:
one introduction part that opens at a first surface of a substrate, the one introduction part being configured to introduce liquid;
a plurality of discharging parts that open at the first surface of the substrate, the plurality of discharging parts being configured to discharge the liquid introduced from the one introduction part;
a channel configured to connect the one introduction part and the plurality of discharging parts in the substrate; and
a plurality of outflow preventing parts disposed to surround respective openings of the plurality of discharging parts, the plurality of outflow preventing parts being configured to prevent advancement of outflow of the liquid from the plurality of discharging parts by using surface tension, wherein
two or more of the plurality of outflow preventing parts are disposed for each opening so as to surround each opening.

2. The liquid handling device according to claim 1, wherein each outflow preventing part includes (A) an opening edge of each discharging part; (B) a step that is disposed at an inner surface of each discharging part so as to surround the opening and to extend toward outside from a side of the center of each discharging part; (C) an annular groove that is disposed outside the opening so as to surround the opening; or (D) an eaves part that extends from the inner surface of each discharging part toward the opening.

3. The liquid handling device according to claim 1, wherein a distance between an opening of the introduction part and the first surface of the substrate is greater than a distance between the opening of each discharging part and the first surface of the substrate.

4. The liquid handling device according to claim 1, wherein the openings of the plurality of discharging parts are flush with each other on a same plane.

5. The liquid handling device according to claim 1,
wherein at a surface of the liquid handling device, hydrophilic treatment is provided in at least a part of a region other than a region between a first outflow preventing part and a second outflow preventing part, the first outflow preventing part being one of the plurality of outflow preventing parts, the second outflow preventing part being another one of the plurality of outflow preventing parts; and
wherein when the liquid is continuously introduced into the plurality of discharging parts from the channel, the first outflow preventing part is a part where the liquid first reaches, and the second outflow preventing part is a part where the liquid reaches last.

6. The liquid handling device according to claim 2, wherein a distance between an opening of the introduction part and the first surface of the substrate is greater than a distance between the opening of each discharging part and the first surface of the substrate.

7. The liquid handling device according to claim 2, wherein the openings of the plurality of discharging parts are flush with each other on a same plane.

8. The liquid handling device according to claim 3, wherein the openings of the plurality of discharging parts are flush with each other on a same plane.

9. The liquid handling device according to claim 6, wherein the openings of the plurality of discharging parts are flush with each other on a same plane.

10. The liquid handling device according to claim 2,
wherein at a surface of the liquid handling device, hydrophilic treatment is provided in at least a part of a region other than a region between a first outflow preventing part and a second outflow preventing part, the first outflow preventing part being one of the plurality of outflow preventing parts, the second outflow preventing part being another one of the plurality of outflow preventing parts; and
wherein when the liquid is continuously introduced into the plurality of discharging parts from the channel, the first outflow preventing part is a part where the liquid first reaches, and the second outflow preventing part is a part where the liquid reaches last.

11. The liquid handling device according to claim 3,
wherein at a surface of the liquid handling device, hydrophilic treatment is provided in at least a part of a region other than a region between a first outflow preventing part and a second outflow preventing part, the first outflow preventing part being one of the plurality of outflow preventing parts, the second outflow preventing part being another one of the plurality of outflow preventing parts; and
wherein when the liquid is continuously introduced into the plurality of discharging parts from the channel, the first outflow preventing part is a part where the liquid first reaches, and the second outflow preventing part is a part where the liquid reaches last.

12. The liquid handling device according to claim 4,
wherein at a surface of the liquid handling device, hydrophilic treatment is provided in at least a part of a region other than a region between a first outflow preventing part and a second outflow preventing part, the first outflow preventing part being one of the plurality of outflow preventing parts, the second outflow preventing part being another one of the plurality of outflow preventing parts; and
wherein when the liquid is continuously introduced into the plurality of discharging parts from the channel, the first outflow preventing part is a part where the liquid first reaches, and the second outflow preventing part is a part where the liquid reaches last.

13. The liquid handling device according to claim 6,
wherein at a surface of the liquid handling device, hydrophilic treatment is provided in at least a part of a region other than a region between a first outflow preventing part and a second outflow preventing part, the first outflow preventing part being one of the plurality of outflow preventing parts, the second outflow preventing part being another one of the plurality of outflow preventing parts; and
wherein when the liquid is continuously introduced into the plurality of discharging parts from the channel, the first outflow preventing part is a part where the liquid first reaches, and the second outflow preventing part is a part where the liquid reaches last.

14. The liquid handling device according to claim 7,
wherein at a surface of the liquid handling device, hydrophilic treatment is provided in at least a part of a region other than a region between a first outflow preventing part and a second outflow preventing part, the first outflow preventing part being one of the plurality of outflow preventing parts, the second outflow preventing part being another one of the plurality of outflow preventing parts; and
wherein when the liquid is continuously introduced into the plurality of discharging parts from the channel, the first outflow preventing part is a part where the liquid first reaches, and the second outflow preventing part is a part where the liquid reaches last.

15. The liquid handling device according to claim 8,
wherein at a surface of the liquid handling device, hydrophilic treatment is provided in at least a part of a region other than a region between a first outflow preventing part and a second outflow preventing part, the first outflow preventing part being one of the plurality of outflow preventing parts, the second outflow preventing part being another one of the plurality of outflow preventing parts; and
wherein when the liquid is continuously introduced into the plurality of discharging parts from the channel, the first outflow preventing part is a part where the liquid first reaches, and the second outflow preventing part is a part where the liquid reaches last.

16. The liquid handling device according to claim 9,
wherein at a surface of the liquid handling device, hydrophilic treatment is provided in at least a part of a region other than a region between a first outflow preventing part and a second outflow preventing part, the first outflow preventing part being one of the plurality of outflow preventing parts, the second outflow preventing part being another one of the plurality of outflow preventing parts; and
wherein when the liquid is continuously introduced into the plurality of discharging parts from the channel, the first outflow preventing part is a part where the liquid first reaches, and the second outflow preventing part is a part where the liquid reaches last.
